(19) United States
(12) Patent Application Publication
(10) Pub. No.: US 2004/0264718 A1
(43) Pub. Date: Dec. 30, 2004

(54) Acoustic signal processing unit

(75) Inventor: Daisuke Arai, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: MITSUBISHI DENKI KABUSHIKI KAISHA

(21) Appl. No.: 10/847,617

(22) Filed: May 18, 2004

(30) Foreign Application Priority Data
Jun. 3, 2003 (JP) 2003-158205

(51) Int. Cl. H03G 5/00; H04R 5/02

(52) U.S. Cl. 381/309; 381/98

(57) ABSTRACT

An acoustic signal processing unit is provided which enables high-speed processing with reducing the amount of calculations. It includes a bandwidth division section for dividing a bandwidth of an acoustic transfer function including information about shapes of external ears and head of a listener; a high frequency component processing section for simplifying characteristics of the high frequency components obtained by the division through the bandwidth division section; and a signal synthesizing section for synthesizing components excluding the high frequency components obtained by the division through the bandwidth division section with the high frequency components passing through processing by the high frequency component processing section.

### BACKGROUND OF THE INVENTION

1. Field of the Invention

The present invention relates to an acoustic signal processing unit that processes an acoustic signal by using an acoustic transfer function and its inverse function. In the specification, the term “acoustic transfer function” refers to an acoustic transfer function including the information on the shapes of the external ears and head of a listener.

2. Description of Related Art

Conventionally, a technique is known which generates a stereo sound field by controlling the direction and distance of sound using the acoustic transfer function and its inverse function. The technique employs a convolution operation for calculating convolution of the acoustic transfer function and its inverse function with an acoustic signal.

In the state where a speaker is placed in front of a listener, assume that an acoustic signal supplied to the speaker is S(w), the acoustic transfer function from the speaker to the left ear of the listener is GL(w), and the acoustic transfer function from the speaker to the right ear of the listener is GR(w), where w is frequency.

To generate the stereo sound field by headphones utilizing the foregoing technique, the left speaker of the headphones is supplied with a convolution signal produced by performing a convolution of the acoustic transfer function GL(w) with the acoustic signal S(w). Likewise, the right speaker of the headphones is supplied with a convolution signal produced by performing a convolution of the acoustic transfer function GR(w) with the acoustic signal S(w). Thus, the headphones generate the same sound pressure as that generated when the acoustic signal S(w) is reproduced by the speaker, thereby enabling the listener to have a feeling as if the sound were heard from the position of the speaker.

In this case, if the headphones are supplied with only the convolution signals of the acoustic transfer functions GL(w) and GR(w) with the acoustic signal S(w), the acoustic transfer functions from the speakers of the headphones to the ears are superimposed excessively on the sound reproduced by the headphones. The excessively superimposed acoustic transfer functions can be canceled out by performing the convolution operation of the inverse function HL(w) of the acoustic transfer function from the left speaker of the headphones to the ear with the convolution signal of the acoustic transfer function GL(w) with the acoustic signal S(w), and by performing the convolution operation of the inverse function HR(w) of the acoustic transfer function from the right speaker of the headphones to the ear with the convolution signal of the acoustic transfer function GR(w) with the acoustic signal S(w).

The digital signal processing technique, which makes remarkable progress today, usually performs the convolution operation using a high-speed DSP (Digital Signal Processor) suitable for the product-sum operation. However, the acoustic transfer functions include information on the reflection and diffraction resulting from the complicated forms of the external ears and head, and have complicated characteristics with a lot of peaks and dips in a high frequency (short wavelength) band.

The acoustic transfer function G(w) and its inverse function H(w) have the relationship “G(w)*H(w)=1” as the functions of the frequency w, where “*” denotes a convolution operation. Considering the convolution of the inverse function H(w) with the acoustic signal S(w), since the acoustic transfer function G(w) has complicated characteristics in a high frequency band, the inverse function H(w) also has complicated characteristics in the high frequency band in order to cancel out the complicated characteristics.

The inverse function H(w) is usually calculated mathematically from the data on the acoustic transfer function G(w) obtained by actual measurement. However, since the acoustic transfer function has the complicated peaks and dips in the high frequency band, the inverse function represented in the time domain takes a long time to converge, thereby lengthening the data representing the inverse function. In contrast, when the acoustic transfer function does not have the complicated peaks and dips, the inverse function can converge in a short time, resulting in a short data length. In an actual apparatus, the data length of the inverse function is limited. Accordingly, the inverse function cannot achieve sufficient canceling effect even if the convolution operation is performed with the original acoustic transfer function.

Furthermore, a slight displacement of the speaker or microphone can result in large changes in the characteristics of the acoustic transfer function. For example, only a few millimeter displacement of the speaker can cause large changes in the characteristics in the high frequency band beyond 8 kHz in particular. This means that a slight displacement of a subject wearing headphones can greatly change the characteristics in the high frequency band of the acoustic transfer function.

Moreover, the acoustic transfer function includes a band having a large effect on the perception of the direction and distance of the sound, and a band without such an effect. Generally speaking, it is said that the band from about 1 kHz to 10 kHz has a large effect on the localization of the sound, whereas the low frequency band of less than 1 kHz and the high frequency band greater than 10 kHz have little effect.

The foregoing stereo acoustic technique using the acoustic transfer functions requires a large amount of calculations to faithfully reproduce the high frequency band of the acoustic transfer functions and their inverse functions. To reduce the amount of the convolution operation, a technique of simplification is known such as smoothing the acoustic transfer functions and acoustic signals over the entire band (see Relevant Reference 1, for example).

As a related technique, Relevant Reference 2 discloses a bandwidth synthesis filter bank and filtering method, a bandwidth division filter bank and filtering method, and an encoding apparatus and decoding apparatus. In the technique, an optimizing section carries out optimization of the prototype filter coefficients held in a prototype filter coefficient holding section by a window function with a tap length. A tap length converter derives a corrected prototype filter with the tap length by rounding off the filter coefficient section at which both ends of the prototype filter subjected to the optimization take the value zero. Thus, it can achieve a high precision bandwidth division processing/bandwidth synthesis processing when carrying out the encoding or decoding of the acoustic signal after the bandwidth division processing.

Relevant Reference 1: Japanese patent application laid-open No. 57-204094/1982.

Relevant Reference 2: Japanese patent application laid-open No. 10-285031/1998.

As for the technique disclosed in the Relevant Reference 1, however, since the information on the frequency band of about 1 kHz-10 kHz, which is important for the localization of the sound, is lost through smoothing, it is hardly suitable for the signal processing for generating the stereo sound field. In addition, the problem is left in that the slight displacement of the wearing position of the headphones can change the high frequency band characteristics greatly. In addition, since the high frequency band higher than 10 kHz contributes little to the stereo acoustic perception, the faithful reproduction of the high frequency band of the acoustic transfer functions only increases the amount of calculations without offering any actual advantages.

### SUMMARY OF THE INVENTION

The present invention is implemented to solve the foregoing problems. It is therefore an object of the present invention to provide an acoustic signal processing unit capable of high-speed processing with reducing the amount of calculations.

According to one aspect of the present invention, there is provided an acoustic signal processing unit comprising: a bandwidth division section for dividing a bandwidth of an acoustic transfer function including information about shapes of external ears and head of a listener; a high frequency component processing section for simplifying characteristics of high frequency components obtained by the division by the bandwidth division section; and a signal synthesizing section for synthesizing components excluding the high frequency components obtained by the division by the bandwidth division section with the high frequency components passing through processing by the high frequency component processing section.

It can reduce the data length of the inverse function of the acoustic transfer function by simplifying the high frequency band of the acoustic transfer function. Accordingly, it can reduce the amount of calculations of the signal processing, thereby offering an advantage of being able to implement a high-speed processing.

### BRIEF DESCRIPTION OF THE DRAWINGS

FIG. 1 is a block diagram showing a configuration of an embodiment 1 of the acoustic signal processing unit in accordance with the present invention;

FIG. 2 is a block diagram showing a detailed configuration of the bandwidth division section as shown in FIG. 1;

FIG. 3 is a diagram illustrating the function of the bandwidth division section as shown in FIG. 1;

FIG. 4 is a block diagram showing a concrete configuration of the bandwidth division processing section as shown in FIG. 2;

FIG. 5 is a block diagram showing a detailed configuration of the high frequency component processing section as shown in FIG. 1;

FIG. 6 is a block diagram showing a detailed configuration of the high frequency signal processing section as shown in FIG. 5;

FIGS. 7A and 7B are diagrams illustrating the bandwidth division operation of the embodiment 1 of the acoustic signal processing unit in accordance with the present invention;

FIG. 8 is a diagram illustrating the discarding operation of the high frequency components of the embodiment 1 of the acoustic signal processing unit in accordance with the present invention;

FIGS. 9A and 9B are diagrams illustrating the smoothing operation of the high frequency components of the embodiment 1 of the acoustic signal processing unit in accordance with the present invention;

FIGS. 10A and 10B are diagrams illustrating the calculating operation of the average value of the high frequency components of the embodiment 1 of the acoustic signal processing unit in accordance with the present invention;

FIG. 11 is a block diagram showing a concrete configuration of the bandwidth division processing section of an embodiment 2 of the acoustic signal processing unit in accordance with the present invention;

FIG. 12 is a block diagram showing a detailed configuration of the high frequency signal processing section of the embodiment 2 of the acoustic signal processing unit in accordance with the present invention; and

FIG. 13 is a block diagram showing a configuration of an embodiment 3 of the acoustic signal processing unit in accordance with the present invention.

### DETAILED DESCRIPTION OF THE PREFERRED EMBODIMENTS

The embodiments in accordance with the invention will now be described in detail with reference to the accompanying drawings.

### Embodiment 1

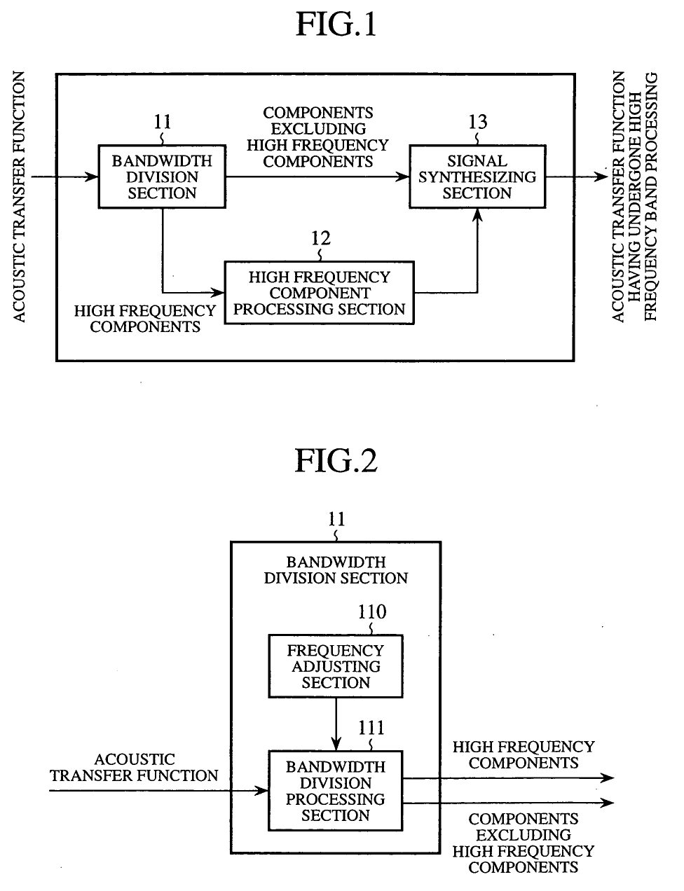

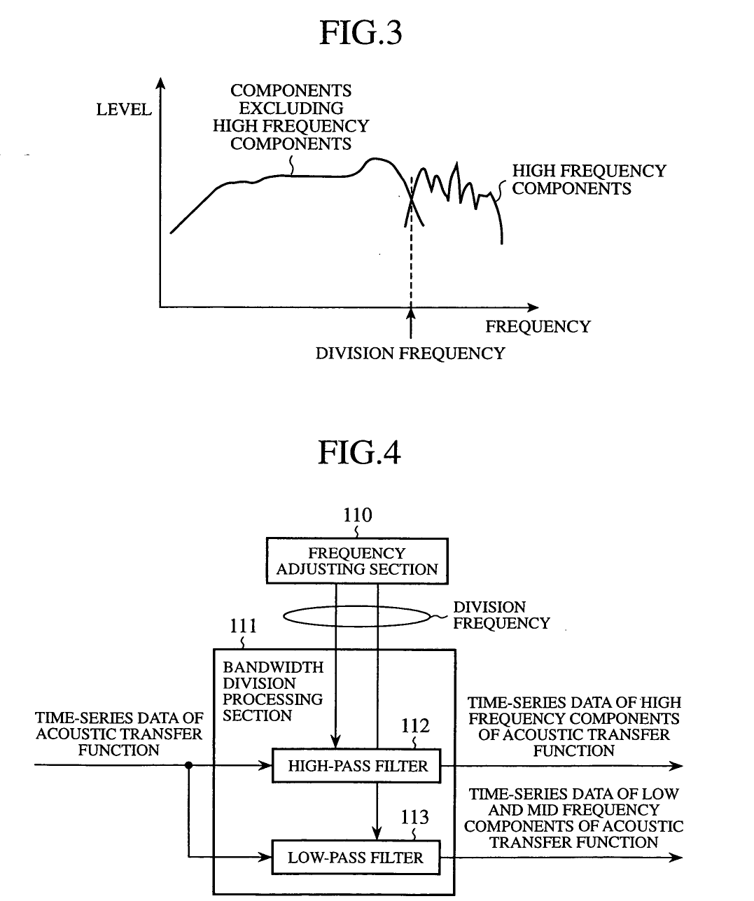

FIG. 1 is a block diagram showing a configuration of an embodiment 1 of the acoustic signal processing unit in accordance with the present invention. The acoustic signal processing unit includes a bandwidth division section 11, a high frequency component processing section 12 and a signal synthesizing section 13.

The bandwidth division section 11, high frequency component processing section 12 and signal synthesizing section 13 are configured by using hardware such as a signal processing LSI or DSP for operating digital data. In this case, the acoustic signal processing unit is configured as a hardware apparatus that processes the high frequency band of the input acoustic transfer function, and outputs it. The bandwidth division section 11, high frequency component processing section 12 and signal synthesizing section 13 can be configured as a processing tool using software. In this case, the acoustic signal processing unit is composed of a computer that stores the processing results in a database.

The bandwidth division section 11 divides the bandwidth of the input acoustic transfer function into high frequency components and components excluding the high frequency components. The bandwidth division section 11 includes a frequency adjusting section 110 and a bandwidth division processing section 111 as shown in FIG. 2.

The frequency adjusting section 110 provides the bandwidth division processing section 111 with a boundary frequency (called “division frequency” from now on) for dividing the bandwidth of the acoustic transfer function. The frequency adjusting section 110 can provide the bandwidth division processing section 111 with any desired division frequency in response to the specification of a user. Alternatively, the division frequency can be fixed to a predetermined frequency. In this case, the frequency adjusting section 110 is not necessary.

The bandwidth division processing section 111 divides the acoustic transfer function supplied from the outside into the “high frequency components” within a band higher than the division frequency fed from the frequency adjusting section 110, and into the “components excluding the high frequency components” in a band lower than the division frequency, and outputs them. The bandwidth division processing section 111 supplies the high frequency components to the high frequency component processing section 12, and the components excluding the high frequency components to the signal synthesizing section 13.

More specifically, the bandwidth division processing section 111 includes a high-pass filter 112 and a low-pass filter 113 as shown in FIG. 4. The high-pass filter 112 and low-pass filter 113 can each consist of an FIR (finite-impulse response) or IIR (infinite-impulse response) filter with the cutoff frequency equal to the division frequency fed from the frequency adjusting section 110.

The high-pass filter 112 passes only the high frequency components of the acoustic transfer function that is input from the outside as time-series data, and outputs them as the time-series data of the high frequency components of the acoustic transfer function. The time-series data of the high frequency components of the acoustic transfer function is supplied to the high frequency component processing section 12. In contrast, the low-pass filter 113 passes only the components excluding the high frequency components of the time-series data of the acoustic transfer function input, and outputs them as the time-series data of the low and midrange components of the acoustic transfer function. The time-series data of the low and midrange components of the acoustic transfer function are fed to the signal synthesizing section 13.

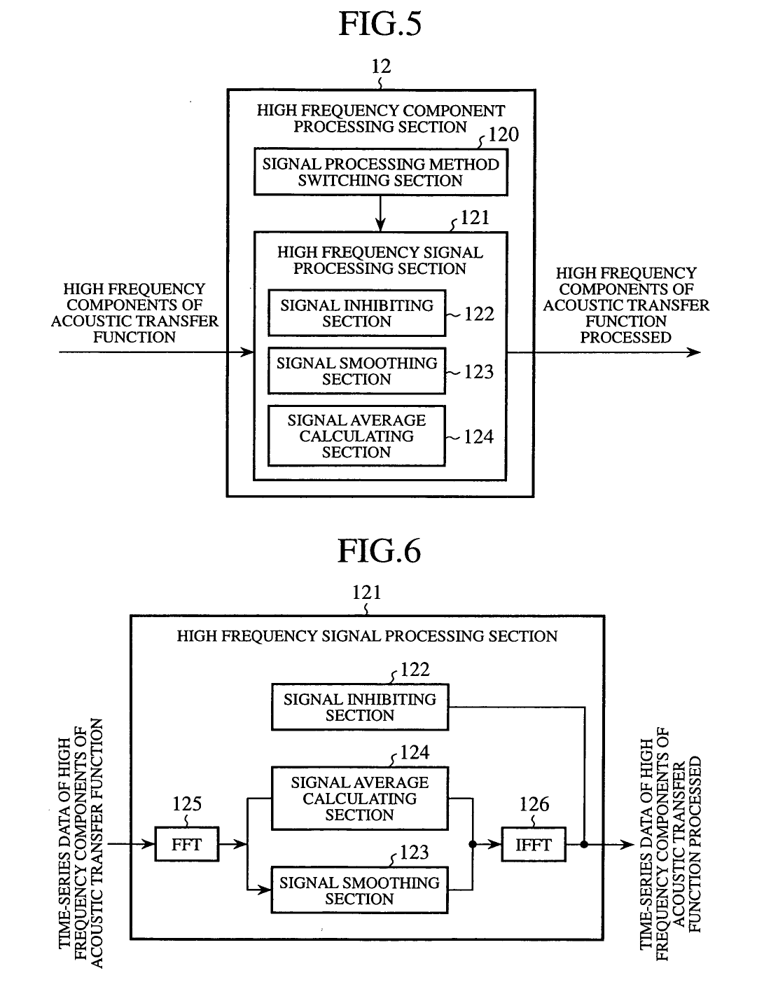

The high frequency component processing section 12 simplifies the characteristics of the high frequency components of the acoustic transfer function, which are obtained by dividing the acoustic transfer function by the bandwidth division section 11. The high frequency component processing section 12 includes a signal processing method switching section 120 and a high frequency signal processing section 121 as shown in FIG. 5. The high frequency signal processing section 121 includes a signal inhibiting section 122, a signal smoothing section 123 and a signal average calculating section 124.

The signal processing method switching section 120 instructs the high frequency signal processing section 121 on the signal processing method. Operating the signal processing method switching section 120, the user can change the signal processing method as he or she chooses.

In response to the instruction from the signal processing method switching section 120, the high frequency signal processing section 121 activates one of the signal inhibiting section 122, signal smoothing section 123 and signal average calculating section 124 to switch the signal processing method.

The signal inhibiting section 122 inhibits the output of the high frequency components of the acoustic transfer function supplied from the bandwidth division section 11. Accordingly, when the signal inhibiting section 122 is activated, the high frequency component processing section 12 supplies the signal synthesizing section 13 with zero as the high frequency components.

Using a method of moving averages, for example, the signal smoothing section 123 smoothes the peaks and dips of the high frequency components of the acoustic transfer function fed from the bandwidth division section 11, and outputs the smoothed high frequency components. Therefore when the signal smoothing section 123 is activated, the high frequency component processing section 12 supplies the signal synthesizing section 13 with the high frequency components smoothed by the signal smoothing section 123.

The signal average calculating section 124 calculates the average value of the levels of the high frequency components of the acoustic transfer function fed from the bandwidth division section 11. Accordingly, when the signal average calculating section 124 is activated, the average value of the high frequency components calculated by the signal average calculating section 124 is supplied to the signal synthesizing section 13.

The signal smoothing section 123 and signal average calculating section 124 handle the data in the frequency domain. To achieve this, the high frequency signal processing section 121 includes, in addition to the signal inhibiting section 122, signal smoothing section 123 and signal average calculating section 124, a fast Fourier transform section (FFT) 125 and an inverse fast Fourier transform section (IFFT) 126 as shown in FIG. 6.

The fast Fourier transform section 125 performs a Fourier transform of the time-series data of the high frequency components of the acoustic transfer function fed from the bandwidth division processing section 111. The frequency domain data resulting from the Fourier transform, that is, the frequency data of the acoustic transfer function, is supplied to the signal smoothing section 123 and signal average calculating section 124. The signal smoothing section 123 and signal average calculating section 124 perform the smoothing and average value calculation of the frequency data of the acoustic transfer function, respectively.

The inverse fast Fourier transform section 126 is supplied with the frequency data representing the high frequency components of the acoustic transfer function smoothed by the signal smoothing section 123, or the frequency data representing the average value of the high frequency components of the acoustic transfer function calculated by the signal average calculating section 124. The inverse fast Fourier transform section 126 performs the inverse Fourier transform of the frequency data fed from the signal smoothing section 123, and outputs the resultant data as the smoothed time-series data of the high frequency components of the acoustic transfer function. It also performs the inverse. Fourier transform of the frequency data fed from the signal average calculating section 124, and outputs the resultant data as the time-series data representing the average value of the high frequency components of the acoustic transfer function.

The signal synthesizing section 13 synthesizes the components excluding the high frequency components of the acoustic transfer function fed from the bandwidth division section 11 and the high frequency components of the acoustic transfer function fed from the high frequency component processing section 12. More specifically, the signal synthesizing section 13 synthesizes the time-series data consisting of the components excluding the high frequency components fed from the bandwidth division section 11 with the time-series data consisting of the high frequency components fed from the high frequency component processing section 12. The time-series data representing the acoustic transfer function obtained by the synthesis by the signal synthesizing section 13 is output as the “acoustic transfer function having undergone the high frequency band processing”.

Next, the operation of the embodiment 1 of the acoustic signal processing unit in accordance with the present invention with the foregoing configuration will be described.

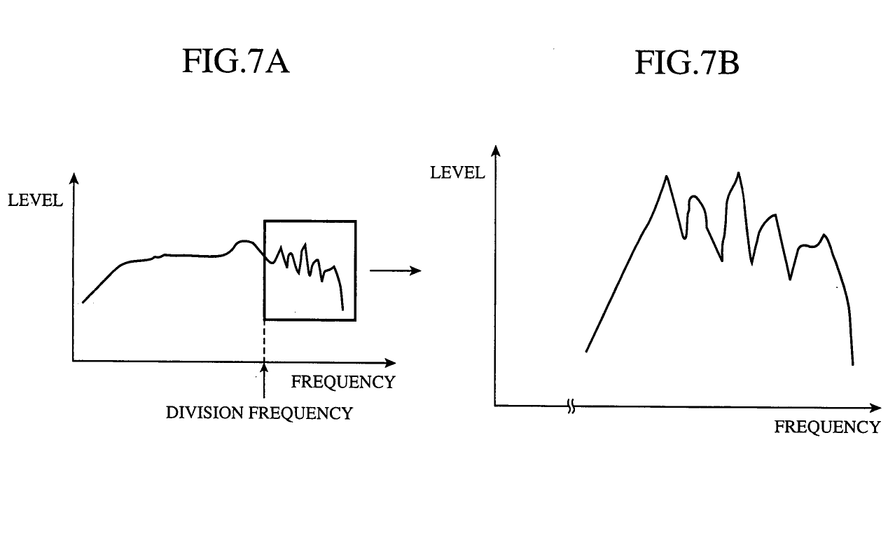

First, the frequency adjusting section 110 of the bandwidth division section 11 instructs the bandwidth division processing section 111 on the division frequency. Receiving the acoustic transfer function from the outside in this state, the bandwidth division processing section 111 divides the acoustic transfer function into the high frequency components and the components excluding the high frequency components at the division frequency as illustrated in FIG. 7A, and outputs them. The high frequency components as illustrated FIG. 7B obtained by the division through the bandwidth division processing section 111 is supplied to the high frequency component processing section 12. On the other hand, the components excluding the high frequency components obtained by the division through the bandwidth division processing section 111 is supplied to the signal synthesizing section 13.

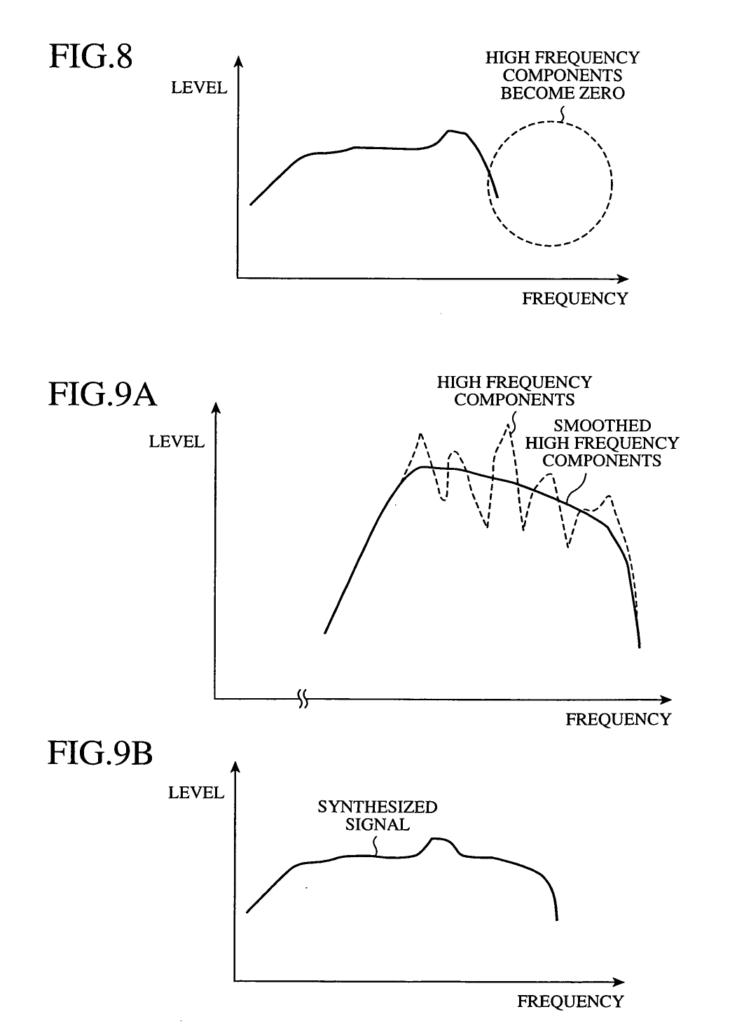

When the signal processing method switching section 120 activates the signal inhibiting section 122, the high frequency signal processing section 121 outputs zero. Thus, the signal synthesizing section 13 outputs the acoustic transfer function without the high frequency components as illustrated in FIG. 8 as “the acoustic transfer function having undergone the high frequency band processing”.

When the signal processing method switching section 120 activates the signal smoothing section 123, the high frequency signal processing section 121 outputs the acoustic transfer function with its high frequency components being smoothed as illustrated in FIG. 9A. Thus, the signal synthesizing section 13 outputs the acoustic transfer function whose high frequency components vary smoothly as illustrated in FIG. 9B as “the acoustic transfer function having undergone the high frequency band processing”.

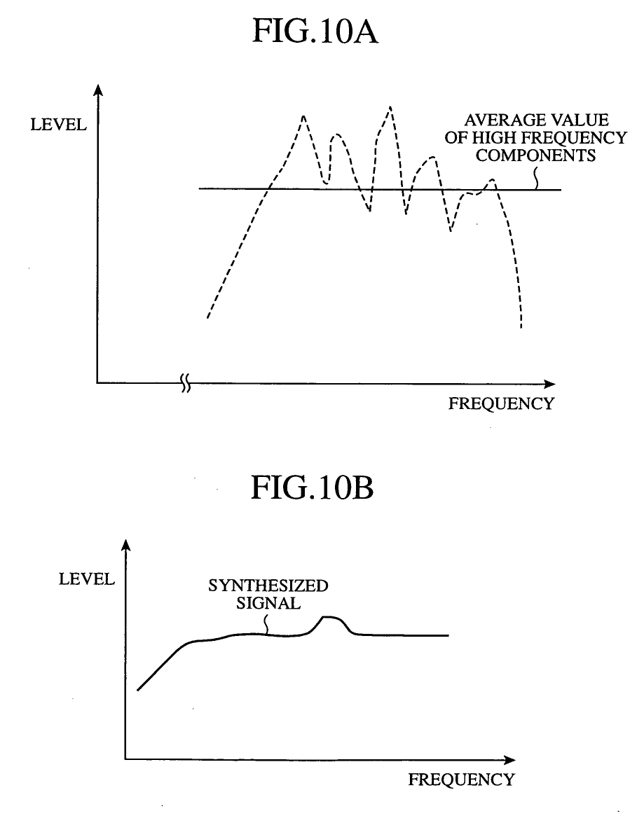

When the signal processing method switching section 120 activates the signal average calculating section 124, the high frequency signal processing section 121 outputs the average value of the high frequency components as illustrated in FIG. 10A as the acoustic transfer function of the high frequency components. Accordingly, the signal synthesizing section 13 outputs the acoustic transfer function with nearly linear high frequency components as illustrated in FIG. 10B.

As described above, since the embodiment 1 of the acoustic signal processing unit simplifies the characteristics of the high frequency components of the acoustic transfer function, it can shorten the data length of the inverse function of the acoustic transfer function. Therefore it can reduce the amount of calculations in the signal processing.

In addition, the embodiment 1 of the acoustic signal processing unit processes only the high frequency components, making it possible to reduce the variations in the characteristics in the high frequency band due to the displacement of the wearing position of the headphones. Accordingly, it can reduce the variations in the characteristics of the high frequency components due to the displacement of the wearing position of the headphones. In addition, since the present embodiment 1 simplifies only the high frequency components having little effect on the sound source localization, it can reduce the influence on the stereo acoustic effect as compared with the method of processing the entire bandwidth.

### Embodiment 2

The embodiment 2 of the acoustic signal processing unit in accordance with the present invention is configured such that the bandwidth division section 11 performs the division processing on the frequency domain data.

The embodiment 2 of the acoustic signal processing unit differs from the embodiment 1 of the acoustic signal processing unit in the following: first, the configuration of the bandwidth division processing section 111 of the bandwidth division section 11; second, the configuration of the high frequency signal processing section 121 of the high frequency component processing section 12; and third, the configuration of a part of the signal synthesizing section 13. The same or like portions to those of the embodiment 1 are designated by the same reference numerals so that the following description is made with centering on the different points.

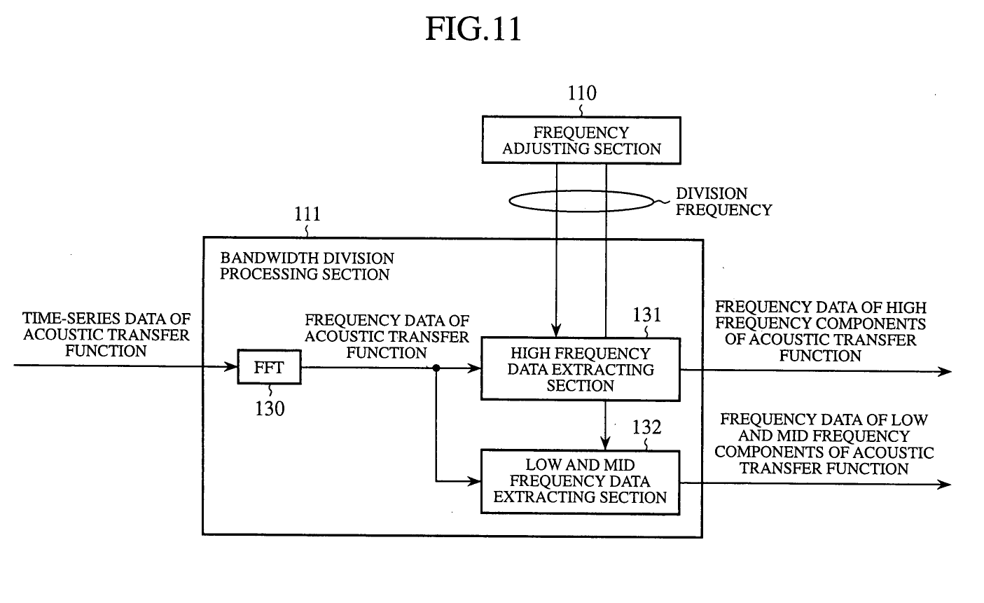

FIG. 11 is a block diagram showing a concrete configuration of the bandwidth division processing section 111 in the bandwidth division section 11 of the embodiment 2 of the acoustic signal processing unit. The bandwidth division processing section 111 includes a fast Fourier transform section (FFT) 130, a high frequency data extracting section 131 and a low and mid frequency data extracting section 132.

The fast Fourier transform section 130 converts the time-series data of the acoustic transfer function input from the outside into the frequency data of the acoustic transfer function by performing a Fourier transform. The fast Fourier transform section 130 supplies the resultant frequency data of the acoustic transfer function to the high frequency data extracting section 131 and low and mid frequency data extracting section 132.

The high frequency data extracting section 131 extracts the high frequency components from the frequency data of the acoustic transfer function fed from the fast Fourier transform section 130, and supplies them to the high frequency component processing section 12 as the high frequency components of the frequency data of the acoustic transfer function. The low and mid frequency data extracting section 132 extracts the components excluding the high frequency components from the frequency data of the acoustic transfer function fed from the fast Fourier transform section 130, and supplies them to the signal synthesizing section 13 as the frequency data of the low and midrange components of the acoustic transfer function.

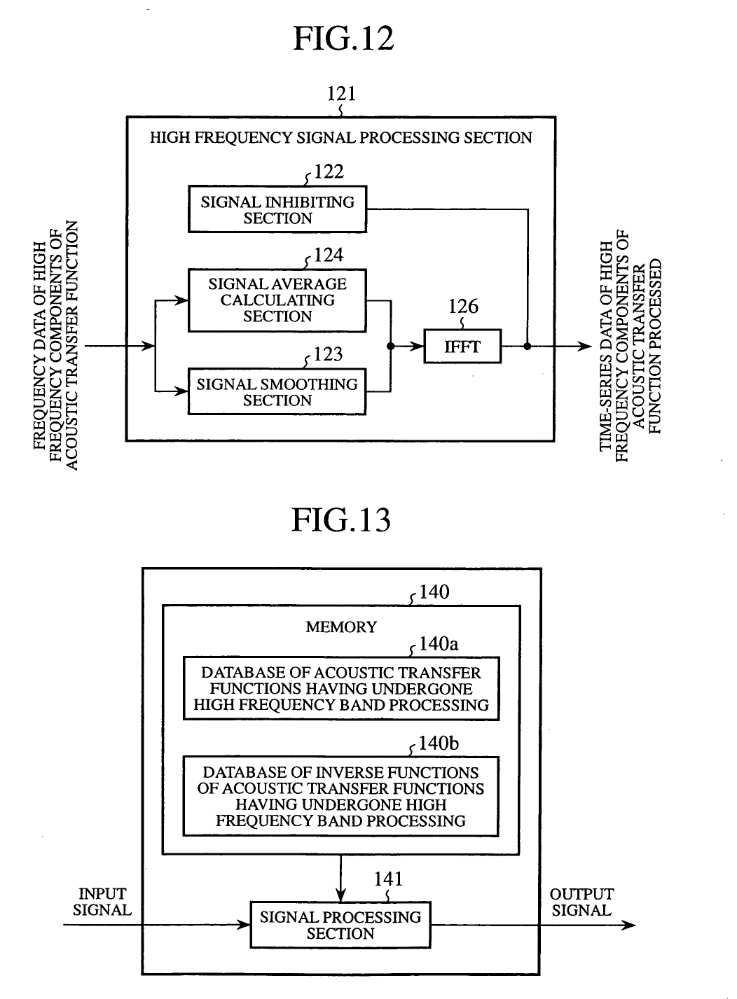

FIG. 12 is a block diagram showing a concrete configuration of the high frequency signal processing section 121 in the high frequency component processing section 12 of the embodiment 2 of the acoustic signal processing unit.

The high frequency signal processing section 121 includes a signal inhibiting section 122, a signal smoothing section 123, a signal average calculating section 124 and an inverse fast Fourier transform section (IFFT) 126. The high frequency signal processing section 121 differs from that of the embodiment 1 in that it does not have the fast Fourier transform section for converting the time-series data to the frequency data. This is because the bandwidth division section 11 supplies the high frequency signal processing section 121 with the frequency data of the high frequency components of the acoustic transfer function.

Although not shown, the signal synthesizing section 13 includes an inverse fast Fourier transform section for converting into the time-series data the components excluding the high frequency components (low and midrange components) of the acoustic transfer function fed from the bandwidth division section 11 as the frequency data. The time-series data consisting of the components excluding the high frequency components of the acoustic transfer function output from the inverse fast Fourier transform section are synthesized with the time-series data consisting of the high frequency components fed from the high frequency component processing section 12, and the synthesized results are output as “the acoustic transfer function having undergone the high frequency band processing”.

With the foregoing configuration, the embodiment 2 of the acoustic signal processing unit in accordance with the present invention operates in the same manner as the foregoing embodiment 1. Accordingly, the description thereof is omitted here.

As described above, the embodiment 2 of the acoustic signal processing unit offers advantages similar to those of the embodiment 1 of the acoustic signal processing unit.

### Embodiment 3

The embodiment 3 of the acoustic signal processing unit in accordance with the present invention generates the stereo sound field using “the acoustic transfer function having undergone the high frequency band processing” produced by the embodiment 1 or 2 of the acoustic signal processing unit.

The embodiment 3 of the acoustic signal processing unit in accordance with the present invention as shown in FIG. 13 is configured by adding a memory 140 and a signal processing section 141 to the embodiment 1 or 2 (not shown in FIG. 13).

The memory 140 includes a first area 140a and a second area 140b. The first area 140a stores as a database the acoustic transfer functions having undergone the high frequency band processing, which are generated by the embodiment 1 or 2 of the acoustic signal processing unit. The second area 140b, on the other hand, stores as the database the inverse functions calculated from the acoustic transfer functions by a processing section not shown.

The signal processing section 141 performs the convolution operation of the acoustic transfer functions read from the first area 140a of the memory 140 and the inverse functions read from the second area 140b with the input signal (acoustic signal) input from the outside, and outputs the operation results as the output signal. The output signal is supplied to the headphones, thereby implementing the stereo sound field.

The embodiment 3 of the acoustic signal processing unit obtains, for the input signal, the acoustic transfer functions and inverse functions which have undergone the high frequency band processing. Accordingly, the present embodiment 3 can reduce the amount of calculations and the scale of the hardware as compared with the configuration that handles the acoustic transfer functions that have not undergone the high frequency band processing.

What is claimed is:

1. An acoustic signal processing unit comprising:
a bandwidth division section for dividing a bandwidth of an acoustic transfer function including information about shapes of external ears and head of a listener;
a high frequency component processing section for simplifying characteristics of high frequency components obtained by the division by said bandwidth division section; and
a signal synthesizing section for synthesizing components excluding the high frequency components obtained by the division by said bandwidth division section with the high frequency components passing through processing by said high frequency component processing section.

2. The acoustic signal processing unit according to claim 1, wherein said high frequency component processing section outputs zero by inhibiting the high frequency components obtained by the division by said bandwidth division section.

3. The acoustic signal processing unit according to claim 1, wherein said high frequency component processing section smoothes the high frequency components obtained by the division by said bandwidth division section, and outputs the smoothed high frequency components.

4. The acoustic signal processing unit according to claim 1, wherein said high frequency component processing section calculates an average value of the high frequency components obtained by the division by said bandwidth division section, and outputs the average value.

5. The acoustic signal processing unit according to claim 1, wherein said high frequency component processing section comprises:
a signal inhibiting section for eliminating the high frequency components obtained by the division by said bandwidth division section;
a smoothing processing section for smoothing the high frequency components obtained by the division by said bandwidth division section;
an average calculating section for calculating an average value of the high frequency components obtained by the division by said bandwidth division section; and
a signal processing method switching section for selecting one of said output inhibit section, said smoothing processing section and said average calculating section to perform the signal processing.

6. The acoustic signal processing unit according to claim 1, wherein said bandwidth division section further comprises a frequency adjusting section for adjusting a frequency used for dividing the bandwidth of the acoustic transfer function.

7. The acoustic signal processing unit according to claim 1, further comprising a memory for storing the acoustic transfer function output from said signal synthesizing section and its inverse function, wherein
said acoustic signal processing unit generates a signal for creating stereo sound field by performing convolution operation of the acoustic transfer function and its inverse function stored in said memory with the acoustic signal input from an outside.
